(19) United States
(12) Patent Application Publication
(10) Pub. No.: US 2006/0003100 A1
(43) Pub. Date: Jan. 5, 2006

(54) CVD process to deposit aluminum oxide coatings

(76) Inventor: Vinod K. Sarin, Boston, MA (US)

Correspondence Address: BANNER & WITCOFF, LTD., 28 STATE STREET, 28th FLOOR, BOSTON, MA, 02109-9601, US

(21) Appl. No.: 11/149,603

(22) Filed: Jun. 10, 2005

Related U.S. Application Data
(63) Continuation of application No. PCT/US02/39879, filed on Dec. 12, 2002.

(30) Foreign Application Priority Data
Dec. 12, 2002 (IB) WO 2004/055236A1

(51) Int. Cl. C23C 16/00

(52) U.S. Cl. 427/248.1

(57) ABSTRACT

Disclosed is a process for depositing Al₂O₃ on a substrate, comprising (a) providing a source of AlCl₃; (b) forming water-gas by reacting hydrogen with one or more oxygen donor compounds having a vapor pressure sufficient to form water-gas at a temperature below about 950° C.; (c) reacting said AlCl₃ with said water-gas to form Al₂O₃; and (d) depositing said Al₂O₃ on said substrate. The process of the present invention achieves effective CVD deposition of aluminum oxide (Al₂O₃) at significantly lower temperatures than previously thought possible on a commercial level. In the present invention, these temperatures are sometimes described as “medium temperatures” or “MT-Alumina”. Preferred substrates include cutting tools which can be coated within the range of about 800°-950° C., which is 100-250° lower than conventional Al₂O₃ CVD deposition temperatures.

### BACKGROUND OF THE INVENTION

Chemical vapor deposition (CVD) of aluminum oxide is used conventionally in various applications in view of the various advantageous properties of Al₂O₃, including hardness; wear resistance, electrical insulating properties and chemical resistance towards oxidizing atmosphere. Natural aluminum oxide or corundum (α-phase) is thermodynamically the stable phase at typical CVD depositions temperatures in the vicinity of 1050° C. In addition to the stable α-phase, aluminum oxide exhibits several metastable allotropic modifications, such as γ, δ, η, θ, κ and χ.

With regard to the cutting tool industry, CVD aluminum oxide-coated cemented carbide cutting tools have been commercially available for more than two decades. Such cutting tools are often used for turning, milling and drilling applications. However, because of the compatibility problems, aluminum oxide typically is not deposited directly onto cemented carbide substrates. Interfacial coatings, based on TiC, Ti(C,N), TIN, Al₂O₃, HfN, etc. sublayers, have been developed in order to enhance adhesion of aluminum oxide to cement substrates, as well as enhance other characteristics such as wear and toughness.

Commercially, CVD aluminum oxide coatings are deposited using the AlCl₃—CO₂—H₂ system. Process parameters typically used are a temperature range between 1000-1050° and a pressure range between 50-100 Torr. Chemical reactions for the formation of Al₂O₃ by the hydrolysis method are:
Source: 2Al+3Cl₂→2AlCl₃ (1)
Water-gas-shift: CO₂+H₂→H₂O+CO (2)
Deposition: 2AlCl₃3+3H₂O→Al₂O₃+6HCl (3)

It has been established that the water-gas formation rate at a fixed temperature depends on the concentration of both H₂ and CO₂ and a maximum water-gas formation rate is obtained at a CO₂/H₂ molar ratio of 2:1. It has been demonstrated that the AlCl₃/H₂O process is a fast reaction, and AlCl₃/O₂ is a very slow reaction process, whereas aluminum oxide deposition from AlCl₃/H₂/CO₂ gas mixture is a medium rate process.

It is well established that the water-gas shift reaction is the critical rate-limiting step for Al₂O₃ formation, and to a great extent, controls the minimum temperature at which Al₂O₃ can be deposited. Extensive work has been done to attempt to deposit CVD Al₂O₃ coatings at lower temperatures. In addition, several CVD Al₂O₃ coatings using other than the AlCl₃—CO₂—H₂ system have been investigated, including AlCl₃/C₂H₅OH, AlCl₃/N₂₀/H₂, AlCl₃/NH₃/CO₂, AlCl₃/O₂/H₂O, AlCl₃/O₂/Ar, AlX₃/CO₂/H₂ (where X is Cl, Br, I), AlBr₃/NO/H₂/N₂ and AlBr₃/NO/H₂N₂. However, none of these systems has been commercially successful, To provide a CVD process for depositing aluminum oxide coatings at temperatures below those previously found necessary for effective deposition on a commercial scale is therefor highly desirable.

### SUMMARY OF THE INVENTION

The problems of the prior art have been overcome by the present invention, which provides a process for chemical vapor deposition (CVD) of aluminum oxide (Al₂O₃). Specifically, the process of the present invention achieves effective deposition of aluminum oxide at significantly lower temperatures than previously thought possible on a commercial level. In the present invention, these temperatures are sometimes described as “medium temperatures” or “MT-Alumina”.

Thus the present invention is directed to a method of depositing Al₂O₃ on a substrate, comprising (a) providing a source of AlCl₃: (b) forming water-gas by reacting hydrogen with an oxygen donor having a vapor pressure sufficient to form water-gas at a temperature below about 950° C.; (c) reacting said AlCl₃ with said water-gas to form Al₂O₃; and (d) depositing the Al₂O₃ on the substrate. Preferably, the temperature of water-gas formation and Al₂O₃ deposition is below about 900° C. Depending upon the substrate being coated, it may be preferable to deposit Al₂O₃ where the temperature of water-gas formation is below about 850° C., or below about 800° C. In general, a suitable temperature range, useful for a wide variety of substrates has been found to be from about 700° C. to about 950° C.

For cutting tool bodies comprising TiC and/or Ti(C,N) coatings, effective deposition in accordance with the present invention has been achieved at temperatures in the range of about 8000-950° C., which is 100-250° lower than conventional deposition temperatures. The process involves the formation of water gas by mechanisms other than the rate-limiting CO₂—H₂ reaction. Instead, water gas is formed using oxygen donors with sufficient vapor pressures to form water gas at temperatures between about 800° C. and 950°.

The chemical vapor deposition process to deposit aluminum oxide in accordance with the present invention is based upon altering the CO₂—H₂ water-gas shift reaction. Water-gas can be generated using H₂—N₂/O₂ based species or fatty acids so as to remove the temperature imitations imposed by the CO₂—H₂ water-gas shift reaction, and thus produce Al₂O₃ at lower deposition temperatures. Thus, in the present invention, alternative sources of oxygen donors are used to form water-gas at desired levels and rates, and at lower temperatures.

Suitable oxygen donors are compounds with vapor pressures sufficient to form water gas. Exemplary compounds include NO₂, H₂O₂ (introduced with a carrier gas) and formic acid, or compounds with vapor pressure similar to formic acid. Compounds with vapor pressures similar to formic acid include nitromethane, trichloracetylaldehyde, trichloroethyloxysilane, dichloroethoxy-methylsilane, 2-propanol, butyric acid, tigaldehyde, ethyl acrylate, methyl methacrylate, ethyl propionate, propyl acetate, isopropyl acetate, methyl butyrate, methyl isobutyrate, isobutyl formate, sec-butyl formate and 1,2-diethoxyethane. Nitric oxide (NO) has also been studied. To date, formic acid has been particularly preferred.

Although the present inventor does not wish to be limited thereby, the following reactions are believed to be operating for these systems:

AlCl₃—NO₂—H₂ System:
2AlCl₃+1.5NO₂+3H₂=Al₂O₃+0.75N₂+6HCl (4)
AlCl₃—HCOOH System:
2AlCl₃+3HCOOH=Al₂O₃+6HCl+3CO (5)

Suitable pressure ranges for CVD alumina deposition in accordance with the present invention are 50 to 100 Torr, with 75 Torr being particularly preferred.

The amount of water-gas content can be manipulated by varying the amount of CO₂ and/or H₂ addition in the reaction system. For example, in the NO₂ system, the level of water-gas formed is much higher than that of the pure CO₂ system when the ratio between CO₂ and NO₂ is varied from 5:1 to 1:5.

Similarly, the effect of H₂ addition to the formation of water-gas is an increase in water-gas content with increasing H₂ concentration in both the HCOOH and NO₂ systems.

The flow rate of the water-gas formation reactant(s) can be controlled to optimize water-gas formation. For example, excellent CVD-alumina coatings on Ti(C,N) and TiC coated tools have been achieved with a formic acid flow rate of 150% and a hydrogen flow rate of %. A commercially available low vapor pressure mass flow controller has been found to be one suitable device used to control the flow rate.

The substrates that be coated by the present invention include solid materials that can withstand the coating process conditions, particularly the coating temperatures. Substrates comprising high temperature heat stable metals, such as high temperature steels, super alloys, and the like are suitable for coating under the present invention. One particularly preferred class of substrates to be coated by the present invention comprises cutting tool bodies. These substrates preferably have at least one layer, and more preferably two or more layers (e.g., interfacial coatings) selected from the group consisting of carbide, carbonitride, oxynitride, oxycarbide, oxycarbonitride or nitride of aluminum, silicon, boron, or Groups IVB, VB and VIB of the Periodic Table.

### BRIEF DESCRIPTION OF THE DRAWINGS

FIGS. 1A and 1B are SEM micrographs showing A) the surface morphology and B) the thickness of MT-Alumina coating deposited on a TiC substrate using 75% of formic acid;

FIGS. 2A and 2B are SEM micrographs showing A) the surface morphology and B) the thickness of MT-Alumina coating deposited on a Ti(C,N) substrate using 150% of formic acid;

FIGS. 3A and 3B are SEM micrographs showing A) the surface morphology and B) the thickness of MT-Alumina coating deposited on a TiC substrate using 150% of formic acid and 6.0 SLM H₂.

### DETAILED DESCRIPTION OF THE PREFERRED EMBODIMENTS

As described above, the present invention is directed to a method of depositing Al₂O₃ on a substrate, comprising (a) providing a source of AlCl₃; (b) forming water-gas by reacting hydrogen with an oxygen donor having a vapor pressure sufficient to form water-gas at a temperature below about 950° C.; (c) reacting said AlCl₃ with said water-gas to form Al₂O₃; and (d) depositing the Al₂O₃ on the substrate. Preferably, the temperature of water-gas formation and Al₂O₃ deposition is below about 900° C. Depending upon the substrate being coated, it may be preferable to deposit Al₂O₃ where the temperature of water-gas formation is below about 850° C., or below about 800° C. In general, a suitable temperature range, useful for a wide variety of substrates has been found to be from about 700° C. to about 950° C.

One preferred embodiment of the present invention provides methods for the medium-temperature (MT) CVD alumina coating of substrates such as cemented carbide cutting tools. As described herein, the method of the present invention involves the formation of water gas by alternative sources of oxygen donors with sufficient vapor pressures to form water gas at desired levels and rates, and at temperatures between about 800° C. and 950°.

The present invention thus provides a process for the CVD of Al₂O₃ on a substrate at so-called “medium” temperatures. In preferred embodiments, water-gas is generated using H₂—N₂/O₂ based species or fatty acids, which have been found to produce Al₂O₃ at lower than conventional deposition temperatures.

One preferred fatty acid in the present invention is formic acid (HCOOH). The preferred HCOOH processing system utilized a commercially available low vapor pressure mass flow controller to provide precise control over the HCOOH introduction into the CVD reactor. Coatings of 1.5 μm thickness were deposited on average. Using HCOOH, alumina coatings were consistently deposited in the temperature range of 800°-875° C.

In order to study the medium temperature alumina coating processing conditions in greater detail, several process parameters such as temperature, pressure and gas flow velocities were varied. Table 1 shows various combinations of temperature and gas flow velocities that were investigated at a deposition pressure of 75 Torr.

TABLE 1
DEPOSITION PRESSURE OF 75 TORR

| 875° C. | | | 850° C. | 825° C. | 825° C. |
|---|---|---|---|---|---|
| 2.0 SLM | 4.0 SLM | 6.0 SLM | 2.0 SLM | 2.0 SLM | 2.0 SLM |
| Hydrogen* | Hydrogen** | Hydrogen*** | Hydrogen* | Hydrogen* | Hydrogen* |
| 75% | 150% | 75% | 75% | 75% | 75% |
| Formic Acid | Formic Acid | Formic Acid | Formic Acid | Formic Acid | Formic Acid |
| 150% | | 150% | 150% | 150% | 150% |
| Formic Acid | | Formic Acid | Formic Acid | Formic Acid | Formic Acid |
| 300% | | 300% | 300% | 300% | 300% |
| Formic Acid | | Formic Acid | Formic Acid | Formic Acid | Formic Acid |

All other reactant gas flows:
*Cl = 50%, Ar = 250%
**Cl = 50%, Ar = 500%
***Cl = 50%, Ar = 750%

Chemical vapor deposition, in general, is very sensitive to chamber contamination. Contaminants that can change the nature of the deposited coating can originate from a variety of sources. In an effort to further reduce the risk of contamination, the substrates that were to be coated were each first cleaned using acetone and then methanol in an ultrasonic bath for ten minutes per solution.

One important factor to the CVD process is the abundance and availability of the critical gases for the reaction. In short, it is important that the reaction chamber be saturated with the gases that are critical to the reaction. For MT-Alumina, water-gas is the key compound in the reaction. As previously mentioned, water-gas is a product of the dissociation of formic acid. Hence, the amount of formic acid in the chamber had a profound effect on the Al₂O₃ coating. As described above, a commercially available low vapor pressure mass flow controller has been found to be one suitable device used to control the flow rate of these critical gases. One especially preferred mass flow controller employed herein was the MKS 1553 available from MKS Instruments, Inc. of Andover, Mass.

Processing parameters derived herein included the following “standard” run:

| Temperature | Pressure | H₂ flow | Cl₂ flow | Ar flow | HCOOH flow |
|---|---|---|---|---|---|
| 875° C. | 75 Torr | 2.0 SLM | 50% | 250% | variable |

This combination produced the highest quality of coatings in terms of surface morphology and thickness. In other words, the surface of the coating was the most uniform in density and grain size. The thickness of these Al₂O₃ coatings averaged approximately 1.5 μm.

In further studies it was found that the following parameters produced coatings that were approximately 25% thicker on average than the standard run:

| Temperature | Pressure | H₂ flow | Cl₂ flow | Ar flow | HCOOH flow |
|---|---|---|---|---|---|
| 875° C. | 75 Torr | 6.0 SLM | 50% | 750% | variable |

A typical MT-Alumina coating grown using the standard run conditions and 75% of formic acid had a surface morphology with individual crystals of a size between 0.8-1.0 μm. These coatings had an average thickness of between 1.0-1.5 μm.

The typical surface morphology and thickness of an MT-Alumina coating deposited using the standard run conditions and 150% of formic acid showed a more uniform surface than those of the 75% formic acid runs. The grains were of an equiaxed shape with an average size of 0.5-1.0 μm. The average thickness for these coatings was 1.5-2.0 μm. For these experimental parameters, the water vapor content was approximately 3.08%.

A typical coating deposited using 150% of formic acid and a revised standard of 6.0 SLM hydrogen and 750% argon showed larger average equiaxed grain size of 0.75-1.25 μm. The average thickness for these coatings was 1.5-2.0 μm. It is important to note that the uniformity and absence of flatness in these coatings has been preserved. For these experiments, 2.16% of the reactant gas was water vapor.

To investigate the effect of deposition temperature on Al₂O₃ deposition, experiments were done between 875° C. and 800° C. in 25° C. increments. All other coating parameters were as follows:

| Temperature | Pressure | H₂ flow | Cl₂ flow | Ar flow | HCOOH flow |
|---|---|---|---|---|---|
| 875° C. | 75 Torr | 2.0 SLM | 50% | 250% | 150% |

These experiments showed that the coating thickness (growth rate) increased slightly with increasing temperature. At a deposition temperature of 800° C. the average coating thickness was 1.25 μm. The thickness of the coatings increased by approximately 20% between 800° C. and 825° C. to an average of 1.5 μm. Between 825° C. and 850° C. the average coating thickness remained the same. An increase of approximately 17% was noticed in coating thickness between experiments done at 850° and 875° C., with an average coating thickness of 1.75 μm.

Experimental results show that as the temperature increases so does that growth rate of Al₂O₃. This suggests that as the temperature increases so does the water vapor concentration. These results are consistent with historical information and theoretical thermodynamic calculations. No significant difference in Al₂O₃ growth rate with temperature was noticed however. Typically, Al₂O₃ coatings are deposited in the 5-10 μm range. The thickest coatings deposited herein were 2.0 μm. The most successful coatings were deposited using a formic acid flow rate of 150% and a hydrogen flow rate of 2000%.

### EXAMPLES

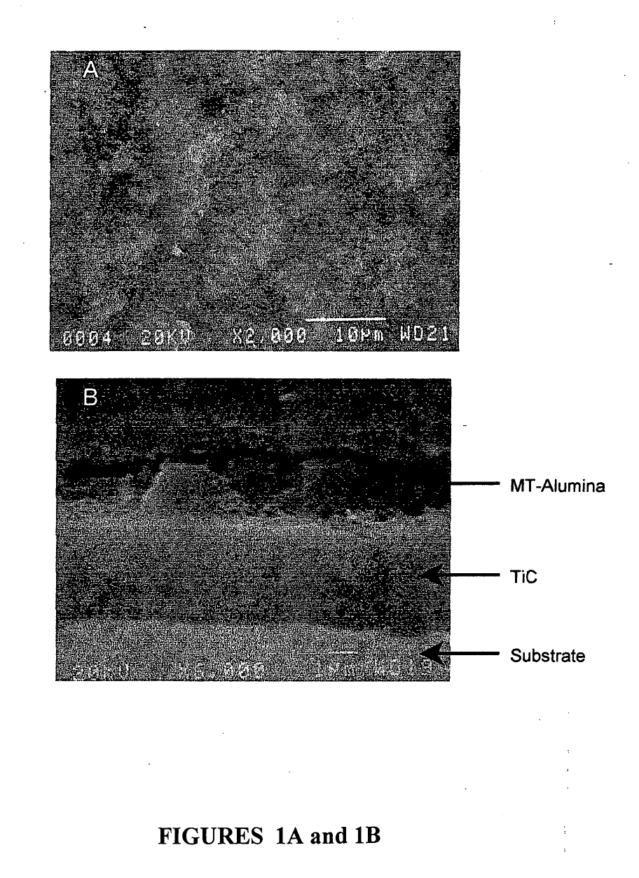

FIGS. 1A and 1B are SEM micrographs showing A) the surface morphology and B) the thickness of MT-Alumina coating deposited on a TiC substrate using 75% of formic acid;

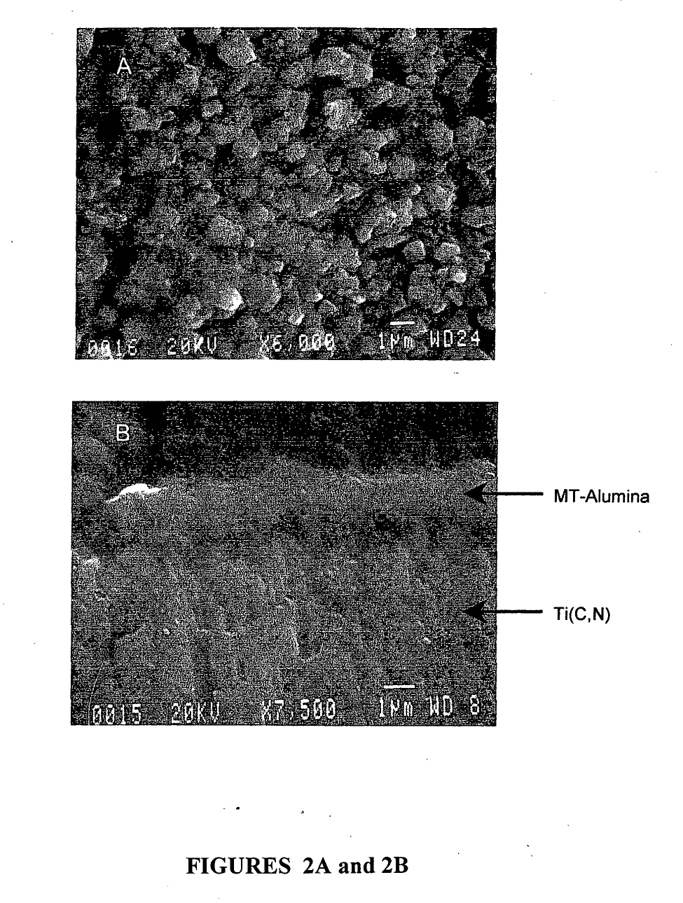

FIGS. 2A and 2B are SEM micrographs showing A) the surface morphology and B) the thickness of MT-Alumina coating deposited on a Ti(C,N) substrate using 150% of formic acid;

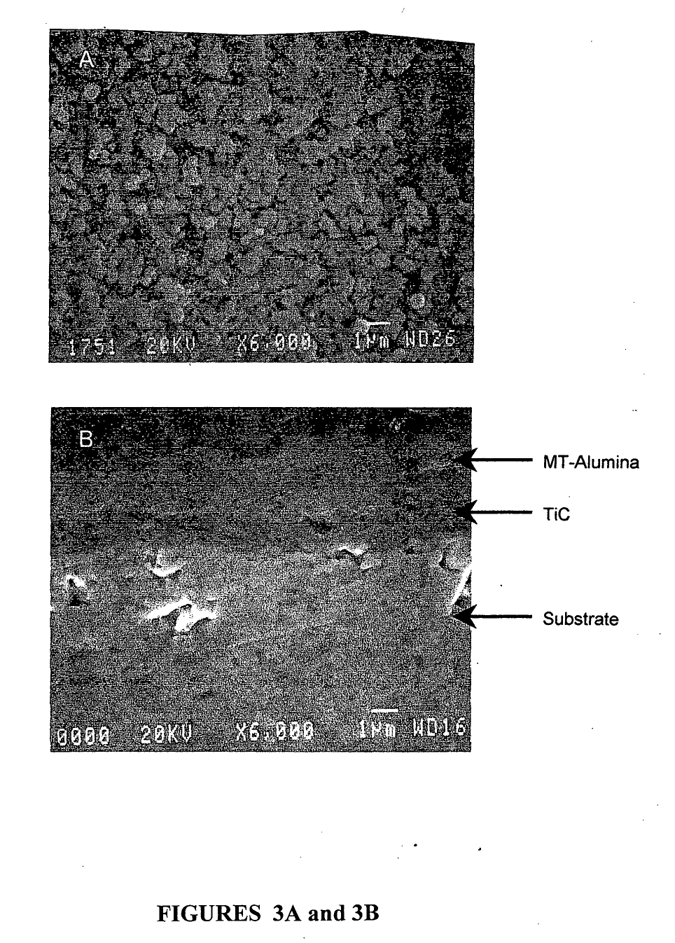

FIGS. 3A and 3B are SEM micrographs showing A) the surface morphology and B) the thickness of MT-Alumina coating deposited on a TiC substrate using 150% of formic acid and 6.0 SLM H₂.

The present invention has been described in detail, including the preferred embodiments thereof. However, it will be appreciated that those skilled in the art, upon consideration of the present disclosure, may make modifications and/or improvements on this invention and still be within the scope and spirit of this invention as set forth in the following claims.

1. A method of depositing Al₂O₃ on a substrate, comprising:
providing a source of AlCl₃;
forming water-gas by reacting hydrogen with one or more oxygen donor compounds having a vapor pressure sufficient to form water-gas at a temperature below about 900° C.
reacting said AlCl₃ with said water-gas to form Al₂O₃; and
depositing said Al₂O₃ on said substrate.

2. (canceled)

3. The method of claim 1, wherein the temperature of water-gas formation is below about 850° C.

4. The method of claim 1, wherein the temperature of water-gas formation is below about 800° C.

5. The method of claim 1, wherein the temperature of water-gas formation ranges from about 700° C. to about 900° C. 950° C.

6. The method of claim 1, wherein said oxygen donor compound is selected from the group consisting of formic acid, nitrogen dioxide, nitrogen monoxide, nitromethane, trichloracetylaldehyde, trichloroethyloxysilane, dichloroethoxy-methylsilane, 2-propanol, butyric acid, tigaldehyde, ethyl acrylate, methyl methacrylate, ethyl propionate, propyl acetate, isopropyl acetate, methyl butyrate, methyl isobutyrate, isobutyl formate, sec-butyl formate, 1,2-diethoxyethane, and mixtures thereof.

7. The method of claim 1, wherein said oxygen donor comprises HCOOH.

8. The method of claim 1, wherein said oxygen donor comprises NO₂.

9. The method of claim 1, wherein said substrate comprises a cemented carbide substrate.

10. The method of claim 9, wherein said substrate further comprises one or more interfacial coatings selected from the group consisting of TiC, Ti(C,N), TiN, Al₂O₃, HfN, or mixtures thereof.

11. The method of claim 10, wherein said substrate comprises TiC.

12. The method of claim 10, wherein said substrate comprises TiN.

13. The method of claim 10, wherein said substrate comprises Ti(C,N).

14. The method of claim 1, wherein said substrate comprises steel.

15. The method of claim 1, wherein the flow rate of said oxygen donor compound is controlled with a mass flow controller.

16. The method of claim 1, wherein said deposition is carried out at a pressure of from about 50 to about 100 Torr.

17. A method of coating a cutting tool body having at least one layer of a carbide or nitride, comprising depositing on said body by chemical vapor deposition a layer of alumina formed by reacting aluminum chloride with water gas formed by reacting an oxygen donating compound with hydrogen at a temperature in the range of 800 to 950° C.

18. The method of claim 17, wherein said substrate further comprises one or more interfacial coatings selected from the group consisting of TiC, Ti(C,N), TiN, Al₂O₃, HfN, or mixtures thereof.

19. The method of claim 17, wherein said oxygen donating compound is selected from the group consisting of wherein said oxygen donor compound is selected from the group consisting of formic acid, nitrogen dioxide, nitrogen monoxide, nitromethane, trichloracetylaldehyde, trichloroethyloxysilane, dichloroethoxy-methylsilane, 2-propanol, butyric acid, tigaldehyde, ethyl acrylate, methyl methacrylate, ethyl propionate, propyl acetate, isopropyl acetate, methyl butyrate, methyl isobutyrate, isobutyl formate, sec-butyl formate, 1,2-diethoxyethane, and mixtures thereof.

20. The method of claim 17, wherein said oxygen donating compound comprises HCOOH.

21. The method of claim 17, wherein said oxygen donating compound comprises NO₂.

22. The method of claim 17, wherein said oxygen donating compound comprises NO.

23. The method of claim 17, wherein the flow rate of said oxygen donating compound and of said hydrogen is controlled by a mass flow controller.

24. The method of claim 17, wherein said flow rate of said oxygen donating compound is controlled between 75-200%.

25. An article of manufacture comprising a substrate coated with alumina by the process of claim 1.

26. The article of manufacture of claim 25, wherein said substrate comprises a metal body.

27. The article of manufacture of claim 26, wherein said metal body comprises a cutting tool body.

28. The article of manufacture of claim 27, wherein said cutting tool body comprises at least one layer selected from the group consisting of a carbide, carbonitride, oxynitride, oxycarbide, oxycarbonitride or nitride of aluminum, silicon, boron, or Groups IVB, VB and VIB of the Periodic Table.

29. The article of manufacture of claim 28, wherein said substrate comprises Ti(C,N).

30. The article of manufacture of claim 28, wherein said substrate comprises TiC.

31. The article of manufacture of claim 26, wherein said metal body comprises steel.
